(19) United States
(12) Patent Application Publication
(10) Pub. No.: US 2026/0114075 A1
(43) Pub. Date: Apr. 23, 2026

(54) LIGHT RECEIVING ELEMENT AND METHOD OF MANUFACTURING THE SAME

(71) Applicant: SUMITOMO ELECTRIC INDUSTRIES, LTD., Osaka (JP)

(72) Inventor: Takeshi OKADA, Osaka (JP)

(73) Assignee: SUMITOMO ELECTRIC INDUSTRIES, LTD., Osaka (JP)

(21) Appl. No.: 19/347,796

(22) Filed: Oct. 2, 2025

(30) Foreign Application Priority Data
Oct. 21, 2024 (JP) 2024-184824

(51) Int. Cl. H10F 77/14; H10F 30/225; H10F 71/00; H10F 77/124

(52) U.S. Cl. CPC H10F 77/147; H10F 30/225; H10F 71/1272; H10F 77/1248

(57) ABSTRACT

A light receiving element includes a first semiconductor layer having a first conductivity type, a second semiconductor layer, a light receiving layer, and a third semiconductor layer having a second conductivity type. The first semiconductor layer, the second semiconductor layer, the light receiving layer, and the third semiconductor layer are stacked in this order. The second semiconductor layer, the light receiving layer, and the third semiconductor layer form a first mesa. The second semiconductor layer has a width smaller than a width of the light receiving layer in a direction in which the light receiving layer extends.

### CROSS REFERENCE TO RELATED APPLICATIONS

This application claims priority based on Japanese Patent Application No. 2024-184824 filed on October. 21, 2024, and the entire contents of the Japanese patent application are incorporated herein by reference.

### TECHNICAL FIELD

The present disclosure relates to a light receiving element and a method of manufacturing the same.

### BACKGROUND

In a light receiving element, a mesa is formed to separate elements (for example, see Patent Literature 1: Japanese Unexamined Patent Application Publication No. 2005-328036).

### SUMMARY

A light receiving element according to the present disclosure includes a first semiconductor layer having a first conductivity type, a second semiconductor layer, a light receiving layer, and a third semiconductor layer having a second conductivity type. The first semiconductor layer, the second semiconductor layer, the light receiving layer, and the third semiconductor layer are stacked in this order. The second semiconductor layer, the light receiving layer, and the third semiconductor layer form a first mesa. The second semiconductor layer has a width smaller than a width of the light receiving layer in a direction in which the light receiving layer extends.

### BRIEF DESCRIPTION OF THE DRAWINGS

FIG. 1 is a plan view illustrating a light receiving element according to an embodiment.

FIG. 2 is a cross-sectional view illustrating the light receiving element.

FIG. 3A is a cross-sectional view illustrating the light receiving element.

FIG. 3B is a cross-sectional view illustrating the light receiving element.

FIG. 3C is a cross-sectional view illustrating the light receiving element.

FIG. 3D is a cross-sectional view illustrating the light receiving element.

FIG. 4A is a cross-sectional view illustrating a method of manufacturing a light receiving element.

FIG. 4B is a cross-sectional view illustrating the method of manufacturing a light receiving element.

FIG. 5 is a cross-sectional view illustrating a light receiving element according to a comparative example.

### DETAILED DESCRIPTION

By applying voltage, a semiconductor layer of a mesa is depleted. An electric field is concentrated on the edge of the depleted light receiving layer, and thus, a dark current may increase. Thus, an object of the present disclosure to provide a light receiving element capable of reducing a dark current and a method of manufacturing the same.

The contents of the embodiments of the present disclosure will be listed and described first.

(1) A light receiving element according to the present disclosure includes a first semiconductor layer having a first conductivity type, a second semiconductor layer, a light receiving layer, and a third semiconductor layer having a second conductivity type. The first semiconductor layer, the second semiconductor layer, the light receiving layer, and the third semiconductor layer are stacked in this order. The second semiconductor layer, the light receiving layer, and the third semiconductor layer form a first mesa. The second semiconductor layer has a width smaller than a width of the light receiving layer in a direction in which the light receiving layer extends. The width of the depletion region is substantially equal to the width of the second semiconductor layer, and is smaller than the width of the light receiving layer. Since an electric field is less likely to be applied to the edge of the light receiving layer, a dark current can be reduced.

(2) In the above (1), the second semiconductor layer may include a multiplication layer and an electric field relaxing layer, and the multiplication layer and the electric field relaxing layer may each have a width smaller than the width of the light receiving layer. The light receiving element is an avalanche photodiode and has high sensitivity. Since the electric field is less likely to be applied to the edge of the light receiving layer, the dark current can be reduced.

(3) In the above (2), the light receiving layer may be formed of indium gallium arsenide, and the multiplication layer may be formed of aluminum gallium arsenide antimonide. An etching rate of the multiplication layer is higher than an etching rate of the light receiving layer. The multiplication layer is etched and the width is reduced.

(4) In the above (2) or (3), the multiplication layer may have a doping concentration lower than a doping concentration in the first semiconductor layer. The multiplication layer is depleted in order. The width of the depletion region is substantially equal to the width of the multiplication layer, and is smaller than the width of the light receiving layer. Thus, the dark current can be reduced.

(5) In any one of the above (1) to (4), the third semiconductor layer may include a second mesa, and the second mesa may have a width smaller than the width of the second semiconductor layer. The electric field is constricted by the second mesa and reaches the layer immediately below the second mesa. The electric field is applied to a portion below the second mesa of the light receiving layer. Since the electric field is less likely to concentrate on the edge of the light receiving layer, the dark current can be reduced.

(6) In any one of the above (1) to (5), the light receiving element may further include a fourth semiconductor layer stacked between the light receiving layer and the third semiconductor layer, and the fourth semiconductor layer may be included in the first mesa and the second mesa. The fourth semiconductor layer is depleted, and thus the capacitance of the light receiving element is reduced.

(7) In any one of the above (1) to (6), the first semiconductor layer may have an n-type conductivity, and the third semiconductor layer may have a p-type conductivity. A pin junction is formed.

(8) A method of manufacturing a light receiving element includes stacking a first semiconductor layer, a second semiconductor layer, a light receiving layer, and a third semiconductor layer in this order, and forming a mesa by performing a wet etching on the second semiconductor layer, the light receiving layer, and the third semiconductor layer. The first semiconductor layer has a first conductivity type. The second semiconductor layer has a second conductivity type. After the wet etching, the second semiconductor layer has a width smaller than a width of the light receiving layer in a direction in which the light receiving layer extends. The width of the depletion region is substantially equal to the width of the second semiconductor layer, and is smaller than the width of the light receiving layer. Since the electric field is less likely to be applied to the edge of the light receiving layer, the dark current can be reduced.

(9) In the above (8), the second semiconductor layer may include a multiplication layer and an electric field relaxing layer. The multiplication layer and the electric field relaxing layer may each have a width smaller than the width of the light receiving layer. The light receiving layer may be formed of indium gallium arsenide. The multiplication layer may be formed of aluminum gallium arsenide antimonide. The wet etching may be performed with an etchant containing citric acid. An etching rate of the multiplication layer is higher than an etching rate of the light receiving layer. The side etching proceeds, and the width of the multiplication layer becomes smaller.

### [Details of Embodiments of Present Disclosure]

Specific examples of a light receiving element and a method of manufacturing the same according to an embodiment of the present disclosure will be described below with reference to the drawings. The present disclosure is not limited to these examples, but is defined by the scope of the claims, and is intended to include all modifications within the meaning and scope equivalent to the scope of the claims.

### Embodiment

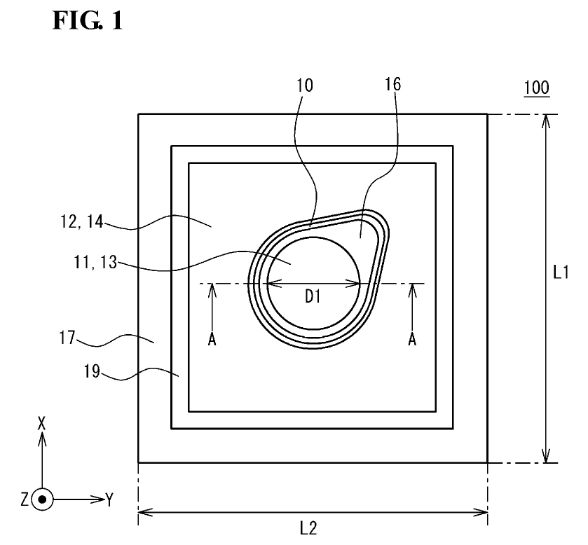

FIG. 1 is a plan view illustrating a light receiving element 100 according to an embodiment. The light receiving element 100 is rectangular in plan view. Two sides of the light receiving element 100 are parallel to an X-axis. The other two sides are parallel to a Y-axis. A Z-axis direction is a thickness direction of the light receiving element 100. An X-axis direction, a Y-axis direction, and the Z-axis direction are orthogonal to each other. A length L1 of the light receiving element 100 in the X-axis direction is, for example, 900 μm. A length L2 of a mesa 10 is, for example, 900 μm. The main surfaces of semiconductor layers such as a light receiving layer 28 extend parallel to an XY plane. The Z-axis direction is a normal direction of the main surface.

The light receiving element 100 is an avalanche photodiode (APD), and detects light having a wavelength of 1550 nm, for example. The light receiving element 100 includes the mesa 10 (first mesa), a terrace 12, a mesa 13 (second mesa), an electrode 14 and an electrode 16, and an outer periphery portion 17. The outer periphery portion 17 is the outer periphery of the light receiving element 100 in the XY plane. A recessed portion 19 is provided inside the outer periphery portion 17 and has, for example, a quadrangular ring shape. The mesa 10, the terrace 12, and the mesa 13 are provided inside the recessed portion 19.

The terrace 12 is a plate-shaped portion, is parallel to the XY plane, and extends outside the mesa 10. The mesa 10 is provided inside the terrace 12 in the XY plane, and protrudes from the terrace 12 in the Z-axis direction. The mesa 13 is provided inside the mesa 10.

The electrode 14 is provided on the terrace 12 and surrounds the mesa 10. The electrode 16 is provided on the mesa 13. The electrode 16 has a ring shape in plan view, and the pad portion protrudes outward from the ring shape. A portion of the mesa 13 surrounded by the electrode 16 serves as a light receiving region 11. The planar shape of the light receiving region 11 is circular. A diameter D1 of the light receiving region 11 is, for example, 200 μm. The outer periphery of the mesa 10 has a curved shape along the electrode 16.

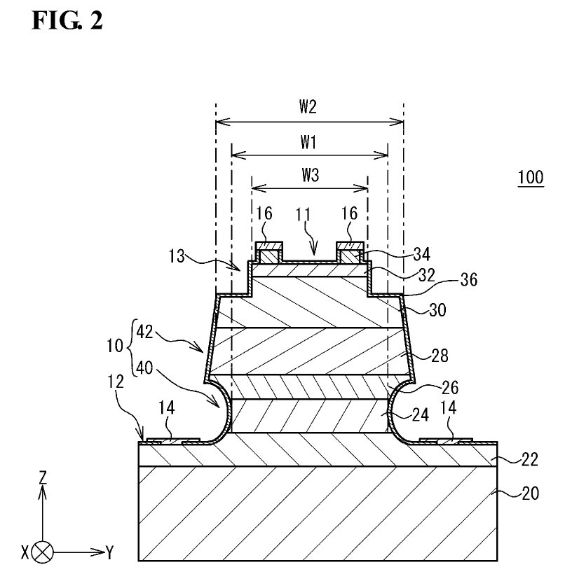

FIG. 2 is a cross-sectional view illustrating the light receiving element 100, and illustrates a cross-section along line A-A of FIG. 1. As illustrated in FIG. 2, the light receiving element 100 includes a substrate 20, a contact layer 22 (first semiconductor layer), a multiplication layer 24 (second semiconductor layer), an electric field relaxing layer 26 (second semiconductor layer), the light receiving layer 28, a cap layer 30 (fourth semiconductor layer), a cap layer 32 (third semiconductor layer), and a contact layer 34 (third semiconductor layer). In the Z-axis direction, the contact layer 22, the multiplication layer 24, the electric field relaxing layer 26, the light receiving layer 28, the cap layer 30, the cap layer 32, and the contact layer 34 are stacked in this order on one surface of the substrate 20.

The contact layer 22 includes the terrace 12. The center portion of the contact layer 22 is located inside the terrace 12 in the XY plane and protrudes from the terrace 12 in the Z-axis direction. The layers from the multiplication layer 24 to the contact layer 34 are stacked on the protruding portion of the contact layer 22. The center portion of the cap layer 30 protrudes in the Z-axis direction beyond the outer periphery portion of the cap layer 30. The cap layer 32 is stacked on the center portion of the cap layer 30. A ring-shaped contact layer 34 is stacked on the upper surface of the cap layer 32. The layers from the center portion of the contact layer 22 to the contact layer 34 form the mesa 10. The center portion of the cap layer 30, the cap layer 32, and the contact layer 34 form the mesa 13.

The mesa 10 has a recessed portion 40 and a wide portion 42. In the Z-axis direction, the recessed portion 40 is located between the wide portion 42 and the substrate 20. The recessed portion 40 includes a portion of the contact layer 22, the multiplication layer 24, and a portion of the electric field relaxing layer 26. The wide portion 42 includes a portion of the electric field relaxing layer 26, the light receiving layer 28, and a portion of the cap layer 30.

The direction of the XY plane is the width direction. In the XY plane, the recessed portion 40 is narrower than the wide portion 42. The wide portion 42 protrudes outward beyond the recessed portion 40 in the XY plane. The side surfaces of the recessed portion 40 are, for example, curved and inwardly constricted. The side surface of the wide portion 42 is inclined from the Z axis, for example, and has a tapered shape that tapers from the bottom to the top in FIG. 2.

Among the layers included in the recessed portion 40, the multiplication layer 24 has the smallest width. The minimum width in the multiplication layer 24 is defined as W1. In the light receiving layer 28, for example, the interface with the cap layer 30 is the narrowest. The minimum width of the light receiving layer 28 is defined as W2. A minimum width W1 of the multiplication layer 24 is smaller than a minimum width W2 of the light receiving layer 28. The difference between the width W1 and the width W2 is, for example, 1 μm to 20 μm. The width W1 is, for example, 310 μm. The width W2 is, for example, 320 μm. A width W3 of the mesa 13 is smaller than the width W1 of the recessed portion 40 and the width W2 of the wide portion 42, and is, for example, 280 μm.

The surfaces of the mesa 10 and the mesa 13 and the terrace 12 are covered with an insulating film 36. An opening is provided in a portion of the insulating film 36 covering the terrace 12. The electrode 14 is provided in the opening and is in contact with the contact layer 22. An opening is provided in a portion of the insulating film 36 covering the contact layer 34. The electrode 16 is provided in the opening and is in contact with the contact layer 34.

The substrate 20 is formed of, for example, indium phosphide (InP). The contact layer 22 is formed of, for example, n-type (first conductivity type) indium gallium arsenide (n-InGaAs). The thickness of the contact layer 22 is, for example, 1.5 μm. The multiplication layer 24 is formed of, for example, aluminum gallium arsenide antimony (AlGaAsSb). The thickness of the multiplication layer 24 is, for example, 0.3 μm. The electric field relaxing layer 26 is formed of, for example, AlGaAsSb. The thickness of the electric field relaxing layer 26 is, for example, 0.6 μm. The multiplication layer 24 and the electric field relaxing layer 26 may be undoped or may be (n-)-type. The multiplication layer 24 and the electric field relaxing layer 26 have a doping concentration lower than a doping concentration of the contact layer 22.

The light receiving layer 28 is formed of, for example, non-doped indium gallium arsenide (i-InGaAs). The thickness of the light receiving layer 28 is, for example, 1 μm. The cap layer 30 is formed of, for example, aluminum indium arsenide (AlInAs). The thickness of the cap layer 30 is, for example, 1.0 μm. The cap layer 30 may be undoped or may be (p-)-type, for example. The cap layer 32 is formed of, for example, (p+)-type (second conductivity type) AlInAs. The thickness of the cap layer 32 is, for example, 0.4 μm. The contact layer 34 is formed of, for example, p-type InGaAs. The thickness of the contact layer 34 is, for example, 0.2 μm. The n-type contact layer 22, the i-type light receiving layer 28, and the p-type cap layer 32 and the p-type contact layer 34 form a pin (positive-intrinsic-negative) junction.

The light receiving element 100 may be formed of a compound semiconductor other than the above. Other semiconductor layers may be included. For example, an anti-pile-up layer may be provided between the light receiving layer 28 and the electric field relaxing layer 26 and between the light receiving layer 28 and the cap layer 30. The electrode 14 and the electrode 16 are formed of metal. The insulating film 36 is formed of an insulator such as silicon nitride (SiN).

When the light receiving element 100 is used, a reverse bias voltage is applied to the light receiving element 100. A positive voltage is applied to the electrode 14. A negative voltage is applied to the electrode 16. The semiconductor layer of the mesa 10 is depleted. The electric field is applied below the mesa 13 in the Z-axis direction. For example, infrared light is incident on the light receiving region 11. The light receiving layer 28 absorbs the infrared light and generates carriers (electron-hole pairs). The electric field causes the carriers to move, and the carriers are output as a photocurrent. The number of carriers increases when the carriers collide with atoms of the multiplication layer 24. High sensitivity is obtained.

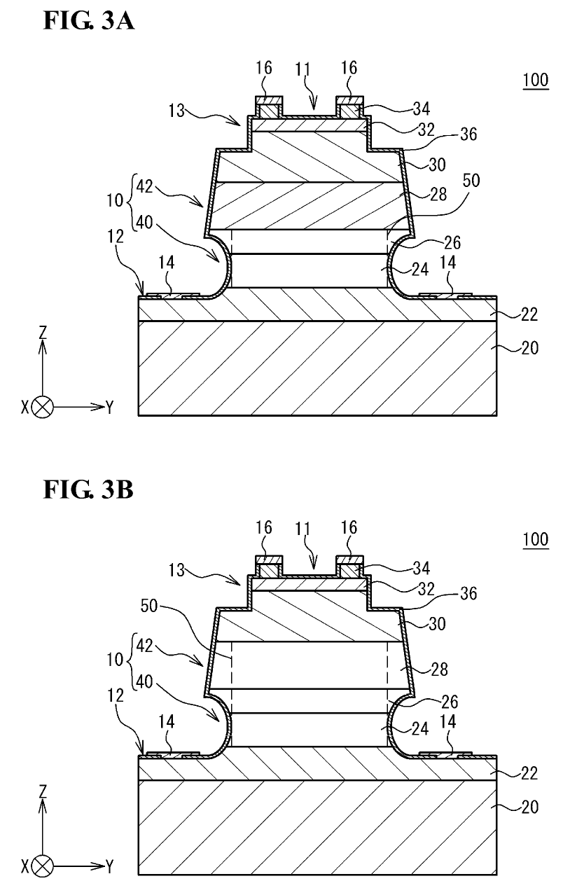

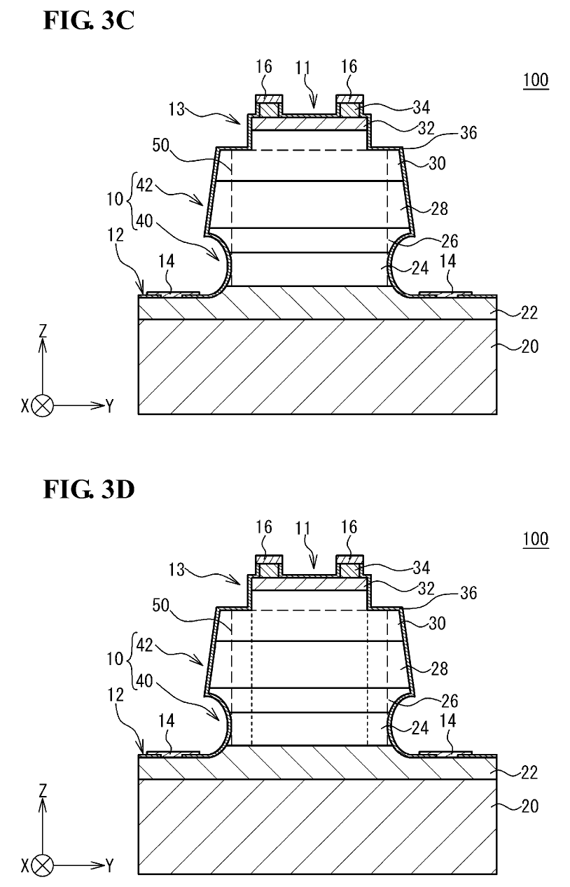

FIGS. 3A to 3D are cross-sectional views illustrating the light receiving element 100. A depletion region 50 is illustrated by a dashed line. The depletion shifts from FIGS. 3A to 3C in response to the application of the voltage.

As illustrated in FIG. 3A, when the voltage is applied, the multiplication layer 24 is depleted first, and the electric field relaxing layer 26 is also depleted. As illustrated in FIG. 3B, the light receiving layer 28 is also depleted. As illustrated in FIG. 3C, the cap layer 30 is also depleted. Since the multiplication layer 24 of the recessed portion 40 is depleted first, the width of the depletion region 50 is determined by the recessed portion 40. That is, the width of the depletion region 50 is substantially equal to the width W1 of the multiplication layer 24 and is smaller than the width W2 of the light receiving layer 28. The portions of the light receiving layer 28 and the cap layer 30 directly above the recessed portion 40 are depleted. The portions of the light receiving layer 28 and the cap layer 30 that protrude beyond the recessed portion 40 are not depleted.

The electric field is applied to the layer to be depleted in the process of depletion. The portions of the light receiving layer 28 and the cap layer 30 that protrude outward beyond the recessed portion 40 are not depleted, and thus the electric field is less likely to be applied to the portions. Since the electric field concentration is less likely to occur at the edge of the light receiving layer 28, the dark current can be reduced.

The dotted line in FIG. 3D schematically represents an electric field. The electric field is applied from the cap layer 30 to the multiplication layer 24. The electric field is constricted by the mesa 13. The width of the electric field is defined by mesa 13. In the Z-axis direction, the electric field is applied to a portion immediately below the mesa 13. The electric field is less likely to be applied to a portion outside the mesa 13 in the XY plane. The electric field is applied to the portions of the cap layer 30 and the light receiving layer 28 that overlaps the mesa 13. The electric field is less likely to be applied to the portions of the cap layer 30 and the light receiving layer 28 outside the mesa 13.

### (Manufacturing Method)

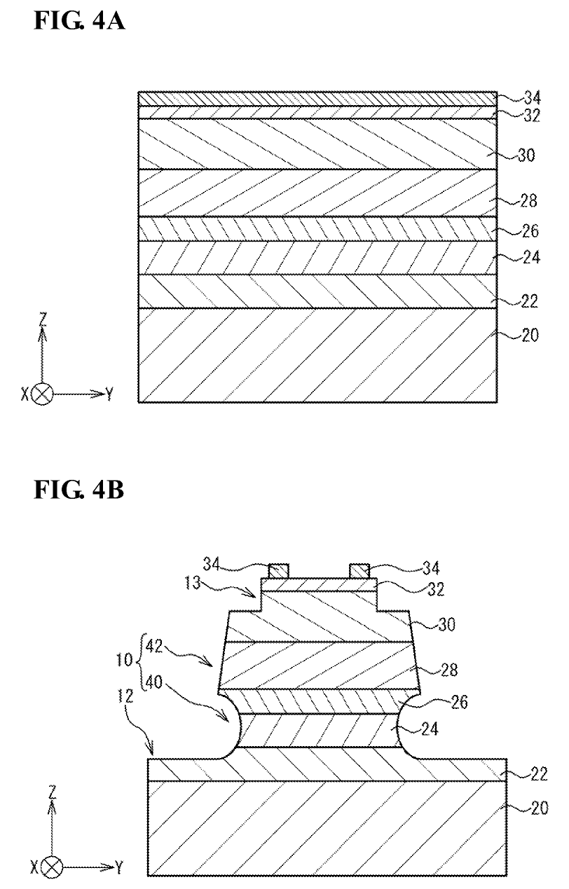

FIGS. 4A and 4B are cross-sectional views illustrating a method of manufacturing the light receiving element 100. As illustrated in FIG. 4A, the contact layer 22, the multiplication layer 24, the electric field relaxing layer 26, the light receiving layer 28, the cap layer 30, the cap layer 32, and the contact layer 34 are epitaxially grown on one surface of the substrate 20 by, for example, metal organic chemical vapor deposition (MOCVD).

As illustrated in FIG. 4B, the terrace 12, the mesa 10, and the mesa 13 are formed by, for example, wet etching. The recessed portion 40 of the mesa 10 is formed by using an etching selectivity between the light receiving layer 28 and the multiplication layer 24. Since the etching rate of the multiplication layer 24 is higher than the etching rate of the light receiving layer 28, the side etching proceeds, and the recessed portion 40 is formed. The material of the semiconductor layer and the etchant are selected so that the etching rate is appropriately set. For example, an etchant containing citric acid is used for the light receiving layer 28 formed of AlGaAsSb and the multiplication layer 24 formed of InGaAs.

Etching may be performed a plurality of times. The mesa 10 and the mesa 13 can be formed by changing the mask and the etchant. Wet etching may be performed a plurality of times. Wet etching and dry etching may be performed. For example, the mesa 10 and the mesa 13 are formed by dry etching. The recessed portion 40 is formed in the mesa 10 by wet etching.

After the mesa 10 and the mesa 13 are formed, the insulating film 36 is formed by a plasma enhanced CVD method (PECVD) or the like. An opening is formed in a portion of the insulating film 36 on the terrace 12. An opening is formed in a portion of the insulating film 36 on the contact layer 34. The electrode 14 and the electrode 16 are formed by vacuum deposition and lift-off. The light receiving element 100 is formed.

### (Comparative Example)

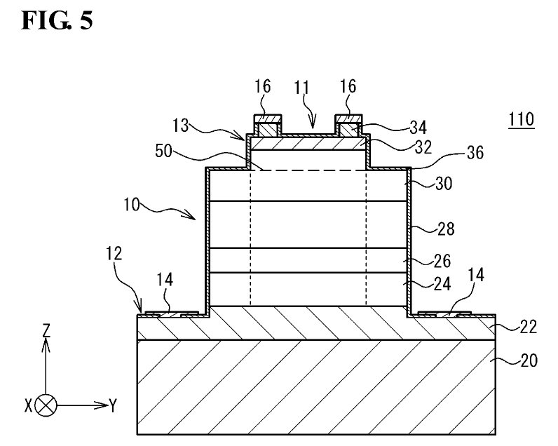

FIG. 5 is a cross-sectional view illustrating a light receiving element 110 according to a comparative example. The mesa 10 does not have a recessed portion and a wide portion. The light receiving layer 28, the electric field relaxing layer 26, and the multiplication layer 24 have the same width.

The dashed line in FIG. 5 represents the depletion region 50. The width of the depletion region 50 is the same as the width of the mesa 10. That is, the depletion region 50 increases to the side surface of the mesa 10. The electric field is concentrated on the edge of the light receiving layer 28, and thus the dark current increases.

According to the embodiment, as illustrated in FIG. 2, the mesa 10 includes the multiplication layer 24, the electric field relaxing layer 26, the light receiving layer 28, and the cap layer 30. The wide portion 42 of the mesa 10 includes the light receiving layer 28. The recessed portion 40 of the mesa 10 includes the multiplication layer 24. The width W1 of the multiplication layer 24 is smaller than the width W2 of the light receiving layer 28. When a voltage is applied to the light receiving element 100, the multiplication layer 24 to the cap layer 30 are sequentially depleted. As illustrated in FIGS. 3A to 3D, the width of the depletion region 50 is substantially equal to the width W1 of the multiplication layer 24 and smaller than the width W2 of the light receiving layer 28. Since the electric field is less likely to be applied to the edge of the light receiving layer 28, the dark current can be reduced.

The recessed portion 40 includes the multiplication layer 24 and the electric field relaxing layer 26. The multiplication layer 24 and the electric field relaxing layer 26 are depleted in response to the application of the voltage. A high electric field is applied to the multiplication layer 24, and carriers are accelerated and collide with atoms of the multiplication layer 24, so that more carriers are generated. That is, the light receiving element 100 is an avalanche photodiode and has high sensitivity. The widths of the multiplication layer 24 and the electric field relaxing layer 26 are smaller than the width W2 of the light receiving layer 28. Since the electric field is less likely to be applied to the edge of the light receiving layer 28, the dark current can be reduced.

The light receiving layer 28 is formed of InGaAs. The multiplication layer 24 is formed of AlGaAsSb. Since there is an etching selectivity between these layers, the recessed portion 40 and the wide portion 42 of the mesa 10 may be formed by wet etching. As the etchant, a citric acid-based etchant such as an aqueous citric acid solution or a citric acid hydrogen peroxide solution is used. The etching rate of the multiplication layer 24 is higher than the etching rate of the light receiving layer 28. The multiplication layer 24 is side-etched to form the recessed portion 40.

The multiplication layer 24 has a doping concentration lower than a doping concentration of the contact layer 22. For example, the multiplication layer 24 may be non-doped or may be (n-)-type. When the voltage is applied to the light receiving element 100, the depletion region 50 increases from the multiplication layer 24. The width of the depletion region 50 is determined by the multiplication layer 24 and is narrower than the light receiving layer 28. Since the electric field is less likely to be applied to the portion of the light receiving layer 28 outside the recessed portion 40, the dark current can be reduced. As illustrated in FIG. 3D, the portion of the light receiving layer 28 that overlaps the recessed portion 40 in the Z-axis direction is depleted and can output carriers.

As illustrated in FIG. 2, the cap layer 32 and the contact layer 34 form the mesa 13. The width W3 of the mesa 13 is smaller than the width W1 of the multiplication layer 24 and the width W2 of the light receiving layer 28. As illustrated in FIG. 3D, the electric field is constricted by the mesa 13 and reaches a portion immediately below the mesa 13. The center portion of the light receiving layer 28 is located immediately below the mesa 13, and a constricted electric field is applied thereto. The carriers generated in the light receiving layer 28 move by the electric field. The edge of the light receiving layer 28 is located outside the mesa 13, and the electric field is less likely to concentrate. Thus, the dark current can be reduced.

The cap layer 30 is provided between the light receiving layer 28 and the cap layer 32. The cap layer 30 is i-type or (p-)-type, and is depleted. The capacitance of the light receiving element 100 can be reduced. High-speed operation is possible.

The contact layer 22 is n-type. The cap layer 32 and the contact layer 34 are p-type. The light receiving layer 28 is i-type. A pin junction is formed. The depletion region 50 is generated in the mesa 10 in response to the application of the voltage. Light incident from the light receiving region 11 can be detected.

A p-type semiconductor layer may be provided between the light receiving layer 28 and the substrate 20, and an n-type semiconductor layer may be provided on the opposite side of the light receiving layer 28 from the substrate 20. The light receiving element 100 may be a photodiode other than the avalanche photodiode.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving element comprising:
a first semiconductor layer having a first conductivity type;
a second semiconductor layer;
a light receiving layer; and
a third semiconductor layer having a second conductivity type,
wherein the first semiconductor layer, the second semiconductor layer, the light receiving layer, and the third semiconductor layer are stacked in this order,
wherein the second semiconductor layer, the light receiving layer, and the third semiconductor layer form a first mesa, and
wherein the second semiconductor layer has a width smaller than a width of the light receiving layer in a direction in which the light receiving layer extends.

2. The light receiving element according to claim 1,
wherein the second semiconductor layer includes a multiplication layer and an electric field relaxing layer, and
wherein the multiplication layer and the electric field relaxing layer each have a width smaller than the width of the light receiving layer.

3. The light receiving element according to claim 2,
wherein the light receiving layer is formed of indium gallium arsenide, and
wherein the multiplication layer is formed of aluminum gallium arsenide antimonide.

4. The light receiving element according to claim 2,
wherein the multiplication layer has a doping concentration lower than a doping concentration in the first semiconductor layer.

5. The light receiving element according to claim 1,
wherein the third semiconductor layer includes a second mesa, and
wherein the second mesa has a width smaller than the width of the second semiconductor layer.

6. The light receiving element according to claim 5, further comprising:
a fourth semiconductor layer stacked between the light receiving layer and the third semiconductor layer,
wherein the fourth semiconductor layer is included in the first mesa and the second mesa.

7. The light receiving element according to claim 1,
wherein the first semiconductor layer has an n-type conductivity, and
wherein the third semiconductor layer has a p-type conductivity.

8. A method of manufacturing a light receiving element, the method comprising:
stacking a first semiconductor layer, a second semiconductor layer, a light receiving layer, and a third semiconductor layer in this order; and
forming a mesa by performing a wet etching on the second semiconductor layer, the light receiving layer, and the third semiconductor layer,
wherein the first semiconductor layer has a first conductivity type,
wherein the second semiconductor layer has a second conductivity type, and
wherein, after the wet etching, the second semiconductor layer has a width smaller than a width of the light receiving layer in a direction in which the light receiving layer extends.

9. The method of manufacturing a light receiving element according to claim 8,
wherein the second semiconductor layer includes a multiplication layer and an electric field relaxing layer,
wherein the multiplication layer and the electric field relaxing layer each have a width smaller than the width of the light receiving layer,
wherein the light receiving layer is formed of indium gallium arsenide,
wherein the multiplication layer is formed of aluminum gallium arsenide antimonide, and
wherein the wet etching is performed with an etchant containing citric acid.
